(19) United States
(12) Patent Application Publication
(10) Pub. No.: US 2004/0218451 A1
(43) Pub. Date: Nov. 4, 2004

(54) Accessible user interface and navigation system and method

(76) Inventors: Joe P. Said, West Lafayette, IN (US); David A. Schleppenbach, West Lafayette, IN (US)

Correspondence Address: CHARLES C. VALAUSKAS, BANIAK PINE & GANNON, Suite 1200, 150 N. Wacker Drive, Chicago, IL, 60606, US

(21) Appl. No.: 10/702,166

(22) Filed: Nov. 5, 2003

Related U.S. Application Data
(60) Provisional application No. 60/423,930, filed on Nov. 5, 2002.

(51) Int. Cl. G11C 7/00

(52) U.S. Cl. 365/222

(57) ABSTRACT

An Accessible User Interface is designed or tailored specifically to a user's disability to maximize access to information. Cross-functional Product Design allows for a manageable subset of core features needed by people with disabilities to access information contained in print and electronic media. An Accessible Feature Design Template is an item-by-item description of the specific features that must be considered when designing an Accessible User Interface product including low vision, blind, learning disabled, mobility impaired, deaf and hard-of-hearing. The Accessible User Interface includes specific features that are matched to the individual's specific needs. The Accessible User Interface of the present invention includes embodiments tailored to each individual's disability or disabilities to provide a person with certain types of sensory, cognitive, or physical disabilities to access a computer or electronic device in a manner functionally equivalent to the user interface experienced by the non-disabled user.

This application claims the benefit of U.S. Provision Application No. 60/423,930 filed Nov. 5, 2002.

FIELD OF THE INVENTION

The present invention relates generally to systems and methods to improve communication for people with disabilities, such as hearing impaired, visually impaired, learning disabled and mobility impaired. In particular, the invention relates to systems and methods of designing an Accessible User Interface for software applications or hardware devices for disabled persons to improve communication.

### BACKGROUND OF THE INVENTION

Modern advances in technology have led to an explosion in the amount of information that is communicated on a daily basis in work, school, and even leisure. The need to communicate effectively and clearly has never been greater than in our modern information age. For a person with any disability that prevents normal means of communication, accessibility of information can prove to be a formidable barrier. Products that can help a wide variety of people with disabilities to better communicate are not only a much-needed tool, but also legislatively mandated through a variety of recent laws, such as the Americans with Disabilities Act, Individuals with Disabilities Education Act and Rehabilitation Act. Section 504 of the Rehabilitation Act states that no individual with a disability can be denied access to any program or activity that receives federal funds due to a disability. Section 508 requires that when Federal agencies develop, procure, maintain, or use electronic and information technology, employees with disabilities have access to and use of information and data that is comparable to the access and use by employees who are not individuals with disabilities. Section 508 also requires that individuals with disabilities, who are members of the public seeking information or services from a Federal agency, have access to and use of information and data that is comparable to that provided to the public who are not individuals with disabilities.

People with a wide range of disabilities, such as deaf and hard of hearing, blind and low vision, learning disabled and mobility impaired are limited in their participation with electronic equipment, for example, computers.

Currently, most computer application software programs include graphical user interfaces. A user interface (UI) is the means by which a user can enter inputs into a computer or electronic device, and receive outputs from that computer or electronic device. Some graphical user interfaces include objects, such as folders, documents, and file cabinets. These objects are displayed as icons on the display screen. The objects are manipulated with a mouse or keyboard controls to perform desired operations. For example, the user can “drag and drop” objects onto one another by clicking an object with a mouse.

Normally sighted individuals find graphical user interfaces intuitive and easy to work with. However, except for an occasional “beep” or similar tone, graphical user interfaces are virtually silent and the vast majority of the information which such interfaces provide to the user is visual. Thus, graphical user interfaces are essentially not usable by the blind or severely visually impaired.

An audible indicator may be used to convey the position of a pointer on the display screen or which particular icon or object the pointer passes over located on the display screen desktop. When passing over an icon or object with a pointer on the display screen controlled by movement of a mouse, certain sounds or audible indicators convey which graphic element is being passed over or selected. Further, an increase in pitch or sound may indicate the position of the pointer on the display screen. In addition, a verbal announcement of the identity of the icon may be outputted using a Text-To-Speech (TTS) synthesizer. These tools allow a disabled person to navigate to find certain elements, but it does not allow access of information in a manner functionally equivalent to the user interface experienced by the non-disabled user.

To effectively interact with a computer application using either a keyboard or a graphical user interface, a user must have a good working knowledge of the natural language used in the interface of the applications. Persons who are cognitively or learning disabled are disadvantaged by using the standard graphical user interface.

For certain programs, graphical user interfaces have attempted to provide selection of objects or icons based on the first letter of a word or by using a letter-based menu selection system to advance through a set of icons or objects. While this interface does make applications more accessible to individuals who have difficulty with the orthography of a language, it is not sufficient to allow one with learning disabilities to effectively access information.

Persons with mobility disabilities, or difficulty in utilizing a keyboard or mouse, may use an electronic touch screen. With a touch screen, the user enters data by touching virtual buttons displayed on the computer display. Normally, a touch screen system uses a touch screen panel which is placed directly over the viewing area of a standard computer display that provides a signal to a computer associated with the computer display indicating where on the surface of the display a stylus or finger is placed.

Despite the advantage of touch screen systems in various applications, they present a barrier to many people with disabilities. Those with limited mobility maybe unable to reach or operate the touch screen surface. Those with impaired vision perceive only the featureless surface of the display screen knowing that it may contain one or more virtual buttons of arbitrary placement and functions. Those with cognitive disabilities are foreclosed from much of the information presented by touch screens. In addition, critical audio information in multi-media presentations or applications will not be received by deaf users.

Although, certain tools exist by which a disabled user may navigate within a user interface or graphical user interface to find certain elements, there does not currently exist any user interface by which a disabled person may access information by means of a software application or hardware device in a manner functionally equivalent to the user interface experienced by the non-disable user.

An object of the present invention is to provide an Accessible User Interface that allows person with certain types of sensory, cognitive, or physical disabilities to access a computer or electronic device in a manner functionally equivalent to the user interface experienced by the non-disable user. The Accessible User Interface is tailored to each individual determined by three components: Cross-functional Product Design, Feature Matching and an Accessible Feature Design Template.

### SUMMARY OF THE INVENTION

Modern society revolves around computers, and the use of computers has spawned several new means of communication that are used in all facets of life, including school and work. Specifically, the World Wide Web, e-mail and Instant Messenger (IM) software are becoming the standards for communication for education, business and personal settings. The present invention provides persons with disabilities access to information by means of a software application or hardware device in a manner functionally equivalent to the user interface experienced by the non-disable user. The specific features of the user interface are matched or “fit” to the individual's specific needs, for example, enlargement of text, font manipulations, voice control or sign language recognition.

The Accessible User Interface allows person with certain types of sensory, cognitive, or physical disabilities to access a computer or electronic device in a manner functionally equivalent to the user interface experienced by the non-disabled user. The Accessible User Interface is designed specifically to the user and his or her disablements by consulting three components: Cross-functional Product Design, Feature Matching and an Accessible Feature Design Template.

The Accessible User Interface is a system composed of a plurality of input techniques, a central processor, and a plurality of output techniques, all of which are designed to allow access to static, dynamic, or real-time flow of information. The input techniques are methods for human/computer interaction whereby disabled users with certain sensory, cognitive, or physical limitations can input data into a computer program or hardware device, for example by speaking, gesturing (sign language), writing, or typing. Likewise, the output techniques are similar methods for the user to receive data from the computer program or the device. The processing step is how the inputs are converted into outputs, and how the core information is accessed and modified. The Accessible User Interface of the present invention includes embodiments of “gh PLAYER”, “gh TOOLBAR”, Accessible Instant Messenger and Accessible Testing System.

As previously mentioned, the information being accessed can consist of three basic information types: static, dynamic, or real-time. Static information consists of information that does not change, for example textbooks or training manuals. The “gh PLAYER” is one embodiment of the Accessible User Interface technology designed to provide access to static information. The “gh PLAYER” interface is primarily designed for output.

Dynamic information is information that can change, but not in real-time. Dynamic information can be largely non-interactive, such as with World Wide Web (WWW) pages or interactive, for example forms and tests. For purposes of this application, the term “interactive” means information that, by design, requires the user to modify or enter data. For example, a form is composed of certain static information (the labels for the text fields) and other interactive information (the actual text fields that must be filled out by the user). The “gh TOOLBAR” is one embodiment of the Accessible User Interface technology designed for access to WWW pages or forms, and the Accessible Testing System is one embodiment designed for access to tests and exams.

Finally, real-time information is information that requires two-way interactivity in real-time, or information that changes quickly enough to require real-time access. The Accessible Instant Messenger (AIM) is one embodiment designed for real-time two-way communication, which allows a disabled user to both send and receive information, and thereby communicate with, a non-disabled user.

All input techniques consist of two main parts: the ability for the user to enter the raw text information, for example by speaking, gesturing (sign language), writing, or typing, and also the ability for the user to indicate formatting and structure for the text as well. For example, the user could use special keystrokes, pull-down menus, voice commands, or even special gestures or handwritten symbols to indicate such things as emotional content, visual formatting, headings and other document structure. Further input from the user as to format and nonverbal meaning may not be necessary in the case of the transmission of text-only messages.

Output modes include text display, Electronic Large Print (eLP), electronic Braille (eBRL), virtual Sign Language (vSL), and synthesized speech (using Text-To-Speech (TTS) technology). eLP permits people with low vision to read documents on any computer wherever they may go even if the computer is not equipped with screen enlargement software. eLP includes a page preview display box so the user may gain perspective on the current display location relative to the entire page. eLP includes functionality to enlarge documents by zooming in and out. eBRL is the electronic version of hard copy Braille with the output as a series of raised dots. This type of output is used in conjunction with either a Refreshable Braille Display, which simulates Braille by vibrating a series of small pins in real-time, or with a Braille Embosser, which prints out a hard-copy of Braille by embossing raised dots on a piece of paper. vSL is useful for people to see gestures and other non-text visual output of the device. Basic units of animation (called visiemes) are strung together into a complete video clip of a signing avatar, or computer generated person. The visiemes can either be composed of video clips of a human signer or consist of video clips of an entirely computer-generated human model. Synthesized Speech uses a rendering engine capable of aurally rendering XML data (in this case, a specific subset of XML called Voice XML), for example, any standard SAPI-compliant (Speech Application Programming Interface) Text-To-Speech (TTS) engine such as the standard Microsoft voices, Scansoft, AT&T, and other commercial voices. The rendering engine works by converting the text output into a string of phonemes and special instructions for emphasis of phonemes (such as changing the volume, speed, or pitch) and concatenating those sound bits into an audio file, such as MP3 or WAV for playback. The synthesized speech may also convey some non-verbal communication elements as well, so that in the above example of the speaker emphasizing a word with his voice, the synthesized speech output would emphasize that particular word as well by increases in volume or a different pitch. In addition, certain structural elements of the text such as headings can be conveyed by the use of different voices.

The processing step of the Accessible User Interface involves information interchange and is handled by specific technologies. Static and dynamic information processing is handled by the Media Conversion Process (MCP). The MCP is a unique XML-based process that takes a variety of inaccessible print or electronic text formats and produces the desired accessible media. The Media Conversion Process is a Multi-input/Multi-Output (MIMO) processing system that is an off-line or not-in-real-time conversion between inputs and outputs.

Real-time information processing is handled by the DEAF-core technologies. User-defined input, responsible for conveying semantic information, and raw analog input, such as text, are converted into a unique XML format (“gh XML”). “gh XML” includes standard XML encoded with accessibility information that allows a user to communicate both verbal (text) and non-verbal (semantic) information as part of the input. “gh XML” is a temporary format which is further converted using XSLT (eXtensible Stylesheet Language Transformations) into individual versions of XML specific to each output. After the “gh XML” is converted into the desired XML format, custom rendering engines specific to the desired output convert the individual version of XML into a viable analog format for display.

There are two aspects to computer output as part of the Accessible User Interface: rendering agents and navigation. Content independent navigation of information (CIDNav) is an application of playback and navigation of a document using a speech recognition interface and computer synthesized or recorded voice response. Documents are divided into hierarchical structures that allow easy and intuitive navigation by voice. The CIDNav system of the present invention is designed to deliver information by speech over the telephone, both wireline and wireless, and Voice Over Internet Protocol (VOIP), or using any specialized computer application, both in analog and digital formats. CIDNav delivers information and enables navigation and playback of the information that is independent of the content in a document. A speech recognition interface is used that includes a tool for document authoring that associates portions of the content with a node. Each node is associated with at least one other node and is assigned identifying data corresponding to associated content in order to provide a User Interface access to the content of the document. The User Interface can be configured to recognize a variety of input, for example, spoken commands, input form a mouse or keyboard, or input from a DTMF (touch-tone signals via a telephone) source.

The present invention is directed to the Accessible User Interface of which the output modes are displayed. Rendering agents are the means by which the outputs are displayed to the user by the computer. A rendering agent processes the information and then causes the computer to build a display of that information, either as a visual display to a video device (such as a monitor), an auditory display to a sound-generating device (such as speakers), or as a tactile display to a haptic device (such as a refreshable Braille display). All of the particular Accessible User Interface applications can utilize a general Dynamic Linked Library (DLL) to render information. In addition to providing many special accessibility features, the DLL customizes Microsoft Internet Explorer to allow rendering of the information in accessible format. Hence, each of the applications of the Accessible User Interface technology utilizes Microsoft Internet Explorer (IE) as a rendering widget to visually, aurally, or haptically display the information on the output device. The DLL includes the conversion engines, such as Text-To-Speech for sound generation, Braille Translation for display on a refreshable Braille display, and XML with Cascading Style Sheets (CSS) support for visual display in Internet Explorer.

The Accessible User Interface is designed or tailored specifically to the user's disabilities by implementing Cross-functional Product Design. Cross-functional Product Design allows for a manageable subset of core features needed by people with disabilities to access information contained in print and electronic media. An Accessible Feature Design Template is an item-by-item description of the specific features that must be considered when designing an Accessible User Interface product including low vision, blind, learning disabled, mobility impaired, deaf and hard-of-hearing. The Accessible User Interface includes specific features that are matched or “fit” to the individual's specific needs, called feature matching. The Accessible User Interface of the present invention includes embodiments of “gh PLAYER”, “gh TOOLBAR”, Accessible Instant Messenger and Accessible Testing System that are specifically tailored to each individuals' disability or disabilities.

### BRIEF DESCRIPTION OF THE DRAWINGS

FIG. 1 is an illustration of the Accessible Instant Messenger according to one embodiment of the present invention.

FIG. 2 is an illustration of the Accessible Testing System according to one embodiment of the present invention.

FIG. 3 is an illustration of one feature of the Accessible Testing System according to one embodiment of the present invention.

FIG. 4 is an illustration of the “gh PLAYER” according to one embodiment of the present invention.

FIG. 5 is an illustration of one feature of the “gh PLAYER” according to one embodiment of the present invention.

FIG. 6 is an illustration of the “gh TOOLBAR” according to one embodiment of the present invention.

### DETAILED DESCRIPTION

The Accessible User Interface allows a person with certain types of disabilities to access a computer or electronic device in a manner functionally equivalent to the user interface experienced by the non-disable user. The Accessible User Interface is designed or tailored specifically to the user's disabilities by assessing three components: Cross-functional Product Design, Feature Matching and an Accessible Feature Design Template.

To maximize the efficiency of the product development process, Cross-functional Product Design is employed. Cross-functional Product Design allows a single product to meet the needs of a variety of disabled users. Cross-functional Product Design allows for the feature set of the Accessible User Interface to be reduced from an impossibly large set to a more manageable subset of core features needed for access.

Disabled users are typically lumped into a generalized pool that describes their specific type of disability. For example, the term “low-vision” is often used to describe people with poor eyesight that is not functional for reading normal print (even after correction), but is functional for basic Orientation and Mobility activities. However, this broad label can apply to many different types of visual impairments and medical conditions. It is often the fact that low-vision users have other types of disabilities that relate to the central problem of not being able to read, such as poor spelling, slow reading speed, and low reading comprehension. These facets of visual impairment can be more readily classified as Learning Disabilities. Hence, a low-vision user could benefit not only from features designed for low-vision users, but also from features designed for learning disabled users.

For example, a cross-functional feature is the use of computer-synthesized speech to read textual information to the user as an output. This helps users without vision to comprehend the document, and it also helps users with reading problems to better understand what they are visually reading by following along with an audio stream. In this way one feature has provided access for a variety of users. The Accessible User Interface is composed of the minimal set of such features, defined by the Accessible Feature Design Template discussed below, that is required for accessibility to the information being rendered.

Feature Matching matches or “fits” specific product features to the individual user's specific needs. The Accessible User Interface of the present invention includes embodiments of “gh PLAYER”, “gh TOOLBAR”, Accessible Instant Messenger and Accessible Testing System that are specifically tailored to each individuals' disability or disabilities.

The Accessible Feature Design Template is an item-by-item description of the specific features that must be considered when designing an Accessible User Interface product. An Accessible Feature Design Template is used to design any new product in order to most effectively allow for feature matching and custom fitting of the Accessible User Interface to the end user. The Accessible Feature Design Template serves as a guideline for the features that should be included in the Accessible User Interface. The Accessible Feature Design Template includes features to ensure the final product is Section 508-compliant and fully accessible to the widest variety of disabled users. Although certain features are useful for multiple impairments, the Accessible Feature Design Template can be broken down into several major categories including low vision, blind, learning disabled, mobility impaired, deaf and hard-of-hearing. The Accessible User Interface includes specific features that are matched to the individual's specific needs.

A low vision user is one having some vision, but no functional vision for the purposes of reading standard text. People with low vision face the challenge of accessing information contained in print and electronic media. The predominant limitation is the size of the text display on a standard computer screen and text printout. The text size is simply too small and needs to be magnified. People with low vision may also have limited reading ability because they have difficulty finding their place on the screen or distinguishing between similar colors. The amount of space between lines of text and the simplicity of the text font type also affects how accessible the media may be.

The tailored Accessible User Interface includes features that maximize the accessibility of print and electronic media for people with low vision including background color, font size, font color, zoom (magnification) control and negative image and gamma control. The low vision user can control background and foreground color for high contrast modes, for example, yellow text on a black background. The user can enlarge/magnify the fonts only (a screen real-estate efficient method of enlarging the information). This process implements a “digital” zoom which employs a “loss-less” algorithm so that the picture does not lose resolution at higher magnification levels. The user can control font color for high contrast mode independent of foreground color for some applications. The user can variably magnify the image without loss of clarity using a digital zoom. This is effective for those elements which can be rendered in XML (or SVG) such as lines and boxes. An optical zoom magnifies complex images and photographs. Further, the user can adjust the display of images so that a high-contrast negative image can be shown, or individual color intensities can be adjusted (useful for color-blind users), which is particularly useful for complex images and photographs.

Sighted people apply a variety of techniques when reading text, entering text into a computer, or producing a text printout. For example, they can edit the text as they type and check for spelling, grammar, logic, or conveniently format the text in a word processor with options on the toolbar menu. Sighted people can also browse electronic media containing pictures, tables, and charts with little effort. Unlike sighted people, persons who are blind face many challenges when accessing information including: seeing text on the computer screen, reading printed material, efficiently navigating electronic media, understanding complex graphs, charts, and diagrams, and completing online forms. A blind user is classified as having no vision. Therefore, a visual method of displaying data is useless and speech ortactile feedback must be rendered. Persons who are blind must rely upon non-visual methods by using audio and tactile formats.

The tailored Accessible User Interface includes advanced audio and tactile formats that maximize the accessibility of print and electronic media. Features of the Accessible User Interface for blind persons include self-voicing content, Text-To-Speech (TTS) data entry, voice controls and keyboard input. Self-voicing content includes text and data fields that speak when the cursor is active on that area or when an object is selected by tabbing between links. A Text-To-Speech (TTS) engine is used so that any information typed in by the user, or selected from menus and forms, can be spoken. The voice of the TTS can be changed to different speakers, and the rate and volume can be controlled, so that the user can customize the listening experience. Advanced controls include pronunciation methods; for example, the ability to voice punctuation and symbols or to tell the user that the word being spoken is an acronym. Further, functions of the program are bound to keystrokes of keyboard input, so that a mouse is not needed to access the data. In addition, instances of references to “clicking” and other mouse activities are appended with specifically defined keyboard instructions.

The learning disabled user is classified as having functional vision but problems with reading, including tracking, processing of symbols, spelling and word meaning. People with learning disabilities may have visual processing problems, motor problems, or problems processing oral instructions. The predominant limitations include problems with spelling, finding their place on the computer screen and comprehending the logical order of the text.

The Accessible User Interface fort he learning disabled includes features that maximize the accessibility of print and electronic media from text highlighting to spelling features and speech voicing control. Print and electronic media includes training manuals, textbooks, forms, exams, statements, and most any other type of print or electronic media.

The tailored Accessible User Interface for the learning disabled include: text highlighting and color control so that the user can follow word-by-word, letter-by-letter or sentence-by-sentence. Speech may accompany the text highlighting and color control to audibly assist the user. A speech engine can spell and repeat words as needed for clarification. The user can request additional information about the particular element, such as a hyperlink to a definition of a word, an announcement that a word is an acronym, an indexed link to another part of the document where the information is repeated. Further, the user can adjust the reading speed of the highlighting and/or voicing of the document so that the reading experience is fully customized. In addition, phonetic highlighting can verbalize words and highlight them by phoneme, so that the user can learn to read by “sounding out” the word.

The mobility impaired user is classified as having problems with using standard input devices, for example a mouse and keyboard, to access the data. People with mobility impairments include people with congenital disabilities, spinal cord injuries, progressive neuralgic disease, and people who are without the use of hands, arms, or legs. The predominant limitation is the ability to use a standard keyboard for typing, navigating electronic media, writing down information, or even turning the pages of a print book.

The tailored Accessible User Interface for the mobility impaired includes features that maximize the accessibility of print and electronic media for people who have difficulties using their hands. A user-definable Keyboard can control the entire set of tools with user-definable keyboard commands. For example, this allows the user to set shortcuts that omit multiple key presses, or to bind all of the keys to the right side of the keyboard. The user can use any pointing device, such as a mouse, to control the tools as well, in cases where the user cannot control or select from a keyboard. Further, the user can use any type of custom selection device, including trackballs, foot pedals, one-handed keyboards, expanded and contracted keyboards, sip-and-puff switches, head-pointing devices, virtual and scanning keyboards. The user can also navigate and enter data using a voice recognition system, which requires no input device at all. From voice recognition capability to user-configured keyboard access and virtual keyboards, people who have mobility impairments can access print and electronic media such as training manuals, textbooks, forms and exams.

The deaf or hard-of-hearing user is classified as having problems with access to any auditory information that the data might contain. People with deafness include people with congenital hearing disabilities, victims of hearing loss, hard-of-hearing users and sign language users. The tailored Accessible User Interface assists people who have difficulties accessing auditory information contained in electronic multimedia products and traditional products like videos and DVD's. The predominant limitation is the ability to access or even realize that auditory information is present and communicating a vital part of the information.

The Accessible User Interface for the deaf or hard-of-hearing includes features that maximize the accessibility of print and electronic media. Captioning allows any audio stream of spoken words displayed as a caption for the user. Further, an auditory system is displayed as visual cues for the user. Visual semantic cues such as coloring and visual formatting of the text or physical modifications to a sign language avatar conveys meaningful information that would ordinarily be non-verbal, for example the emotional state of the speaker. Further, the Accessible User Interface can display data as sign language using a computer-generated sign language avatar, as opposed to captioned text which many deaf users have difficulty in reading. In addition, the user can navigate and enter data using a sign language recognition system.

The Accessible Instant Messenger (AIM) is one embodiment of the Accessible User Interface. It utilizes a modified version of Internet Explorer as the text rendering engine. Traditional Instant Messaging programs use a proprietary protocol that is not understood by any other instant-messaging services (such as America On-Line, Microsoft, Yahoo and ICQ). Therefore, the format of the data depends on the IM utility used. Messages and connection information are maintained on servers controlled by the provider of the IM utility. AIM works entirely at the client-side, meaning that any of the four major IM protocols mentioned above can be supported, in addition to other proprietary protocols. Changes in the IM protocol do not affect the AIM client as it serves only as a front end for the core IM transfer technology employed by the major IM vendors.

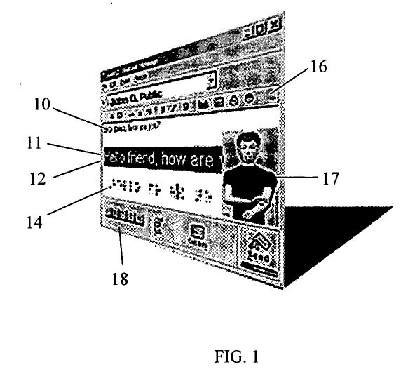

FIG. 1 is an illustration of the Accessible Instant Messenger according to one embodiment of the present invention. The Accessible Instant Messenger provides access to real-time information. In addition to standard Instant Messaging tools, features of the Accessible Instant Messenger may include standard text captioning 10, enlargement of text 11 as well as high-contrast 12 to enable users with vision disabilities access to information contained in print and electronic media. Further, the Accessible Instant Messenger may include a Braille output feature 14 for users that are blind. The Braille output feature 14, or electronic Braille (eBRL), prints out a hard-copy of Braille by embossing raised dots on a piece of paper. The semantic markup toolbar 16 includes formatting controls for semantic cues such as coloring and visual formatting of the text or physical modifications to a virtual sign language avatar 17 to convey meaningful information that would ordinarily be non-verbal, for example the emotional state of the speaker. The Accessible Instant Messenger may also include playback controls 18 for synthesized speech output.

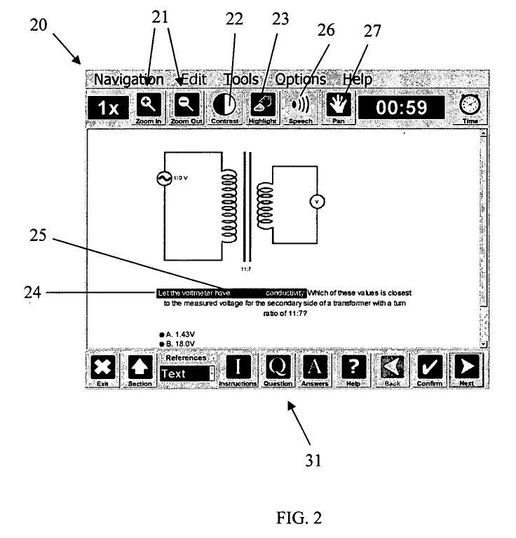

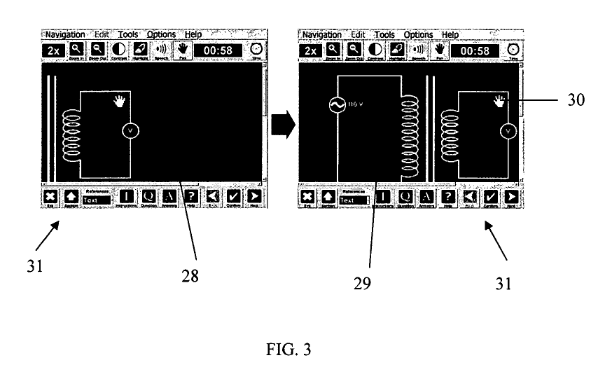

FIG. 2 is an illustration of the Accessible Testing System according to one embodiment of the present invention. The Accessible Testing System provides a disabled user access to dynamic information such as a test or exam. The Accessible Testing System is composed of custom software and a dedicated computer or hardware device. With the Accessible Testing System, the user has the ability to interact with the output information, for example, by answering questions, navigating the electronic media and composing essays. In reference to FIG. 2, the Accessible Testing System includes a top toolbar 20 with a variety of buttons for text and image manipulation. Zoom buttons 21 magnify or reduce the size of text or images. Contrast button 22 varies the color and contrast of text and images. Highlight button 23 provides word-by-word highlighting 24 to assist the user in reading the text. Word-by-word highlighting 24 highlights the entire segment or sentence. Further, particular word highlighting 25 highlights a single word or phrase in a contrasting color to increase the contrast of the text. Speech button 26 outputs synthesized speech. Pan button 27 allows the user to magnify the text or image as illustrated in FIG. 3.

In reference to FIG. 3, the first image 28 is magnified to a second image 29. The Pan button 27 allows the user to scroll the magnified image 29 in any direction using a “grabber hand” icon 30. The “grabber hand” icon 30 is controlled by a mouse or keyboard. In addition, the Accessible Testing System includes a bottom toolbar 31 that allows the user to navigate the test or exam. The bottom toolbar 31 includes navigation features for example, exiting the test by question or section. Further, the bottom toolbar 31 may include a reference tool, test instructions, help, back and next question navigation, question tool and an answer tool that allows a user to navigate to the answer sheet.

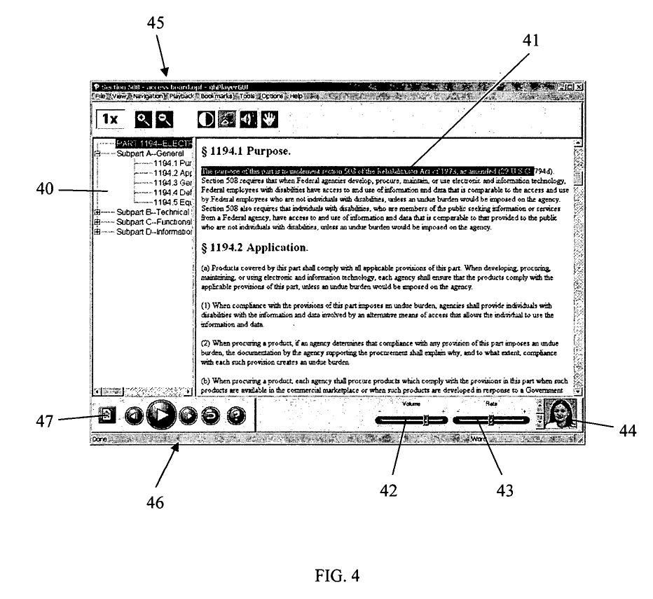

The “gh PLAYER” is an embodiment of the Accessible User Interface technology designed to provide access to static documents, for example books and manuals. FIG. 4 is an illustration of the “gh PLAYER” according to one embodiment of the present invention. Several media types are associated with the “gh PLAYER” technology, including Digital Talking Book (DTB). Electronic Braille (eBRL) and Electronic Large Print (eLP) media supplements the core DTB.

Digital Talking Books (DTB) include marked-up text files with synchronized speech. With DTBs and feature-rich playback software, persons with print-disabilities can read books with ease, save time finding information, benefit from flexible reading solutions, and improve reading productivity. The “gh PLAYER” assists users to locate information quickly.

In reference to FIG. 4, the “gh PLAYER” enlarges text, enhances contrast, scrolls text, spells words, provide hyperlinked definitions of unknown words, and speak the text as a user adjustable rate and voice level. The navigation tree window 40 navigates the book or document at varying levels of granularity. Each subpart of the document can be expanded to present various sub components of each subpart from which the user can select to navigate next. As with CIDNav, the user can navigate by chapters, titles, headings, or by any other navigational node. Further, the user can go directly to a specific page or search the entire book or an individual section for keywords.

The “gh PLAYER” includes synchronized multimedia where audio, video, text and images play precisely in concert with each other. For instance, highlighting of each word 41 in a Digital Talking Book can be followed while listening to the corresponding audio speech output. The volume control 42 allows the user to adjust the volume of the Text-to-Speech engine or playback of recorded voice at a specific decibel level. In addition, the rate control 43 allows the user to adjust the speed or words per minute of the Text-to-Speech engine or playback of recorded voice.

An image 44 can be depicted while voicing a descriptive narrative. The image 44 can be an animated interpretation or a signing avatar that the user can reference while following the text captioning. Synchronized multimedia even provides the power to display English text with Spanish audio.

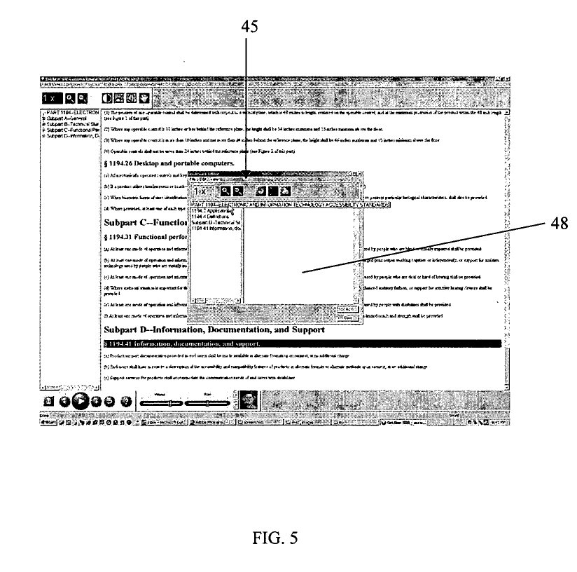

The top toolbar 45 includes buttons for features such as zoom to magnify or reduce the size of text, contrast to increase visibility of a specific word in text, highlight to track placement or increase visibility of text, speech to voice a descriptive narrative and pan for magnification and navigation. The bottom toolbar 46 includes features such as play, pause, next, repeat, help and bookmark. The bookmark button 47 opens the bookmark feature 48 in separate sub-window as shown in FIG. 5. The bookmark feature 48 indicates bookmarks or places of interest of the user, for example where to find an important fact. The user can navigate instantly to the bookmark by selecting the bookmark by name. In addition, the user can input notes for each bookmark. The bookmark sub-window also includes the top toolbar 45 for features of zoom, open, delete and print.

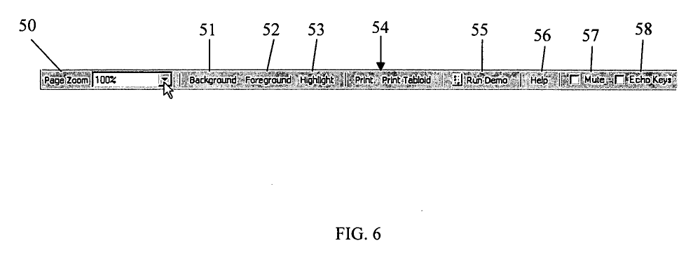

FIG. 6 is an illustration of the “gh TOOLBAR” according to one embodiment of the present invention. The “gh TOOLBAR” is designed to provide access to dynamic information such as WWW pages or forms. One embodiment of the “gh TOOLBAR” is a plug-in, or dockable toolbar, for other programs such as Microsoft Internet Explorer or Microsoft Word. FIG. 6 illustrates the “gh TOOLBAR” in enabled mode. It may also exist in disabled mode, allowing it to be resident in a computer program without being functional so as not to interfere with the ordinary operation of the computer program. In the enabled mode, the “gh TOOLBAR” includes a zoom feature 50 that magnifies or reduces the image in the main display.

The main display can be a display of a software application, for example Internet Explorer or Microsoft Word. The “gh TOOLBAR” includes background color control 51 and foreground color control 52 for the user to adjust the color or contrast of the document or text for increased visual depiction. For example, a user that is color blind can adjust the document to high contrast. Highlighting control 53 allows the user to highlight the information as they read along. Highlighting can be adjusted to different levels of granularity such as by sentence, word, paragraph, or letter. The print control 54 allows the user to print a hard copy of the document including any changes applied by the user. For example, a blind person can print documents in electronic Braille (eBRL) or a low vision user can print documents in large print. The open file control 55 opens a file or document, for example run demo runs a demonstration of the “gh TOOLBAR” features. The help control 56 provides documentation on the “gh TOOLBAR” including the keyboard and mouse techniques needed to activate the “gh TOOLBAR” features and functions. The help file documentation is a WWW document that is viewable using the “gh TOOLBAR” so that no other software applications are needed for accessibility. The mute control 57 enables or disables synthesized speech. When the mute control 57 is selected, or the box is checked, synthesized speech is off. When the mute control 57 is de-selected, or the box is not checked, synthesized speech conveys information for the application interface. Echo key control 58 allows the user to hear speech synthesis of the keys as they are pressed on the keyboard. This allows, for example, a blind user to enter fields in a form.

The Accessible User Interface of the present invention includes embodiments of “gh PLAYER”, “gh TOOLBAR”, Accessible Instant Messenger and Accessible Testing System that are specifically tailored to each individuals' disability or disabilities. Cross-functional Product Design allows for a manageable subset of core features needed by people with disabilities to access information contained in print and electronic media. An Accessible Feature Design Template is an item-by-item description of the specific features that must be considered when designing an Accessible User Interface product including low vision, blind, learning disabled, mobility impaired, deaf and hard-of-hearing. Feature matching matches or fits specific features to the individual's specific disability or disabilities to provide an Accessible User Interface that allows a person with certain types of sensory, cognitive, or physical disabilities to access a computer or electronic device in a manner functionally equivalent to the user interface experienced by the non-disabled user.

While the present inventions and what is considered presently to be the best modes thereof have been described in a manner that establishes possession thereof by the inventors and that enables those of ordinary skill in the art to make and use the inventions, it will be understood and appreciated that there are many equivalents to the exemplary embodiments disclosed herein and that myriad modifications and variations may be made thereto without departing from the scope and spirit of the inventions, which are to be limited not by the exemplary embodiments but by the appended claims.

We claim:

1. An accessible user interface and navigation system and method comprising:
accessing a manageable subset of core features needed by a user with a disability to access information;
choosing specific features that are matched to said user's disability; and
selecting an accessible user interface tailored to said user's disability to allow said user access to information.
